(19) United States
(12) Patent Application Publication
(10) Pub. No.: US 2025/0040377 A1
(43) Pub. Date: Jan. 30, 2025

(54) DISPLAY PANEL AND DISPLAY DEVICE

(71) Applicant: LG Display Co., Ltd., Seoul (KR)

(72) Inventors: Dongil CHU, Paju-si (KR); MinJoo KIM, Paju-si (KR); Sukhyun KANG, Paju-si (KR)

(73) Assignee: LG Display Co., Ltd., Seoul (KR)

(21) Appl. No.: 18/785,422

(22) Filed: Jul. 26, 2024

(30) Foreign Application Priority Data
Jul. 28, 2023 (KR) 10-2023-0098653

(51) Int. Cl. H10K 59/131; H10K 59/122

(52) U.S. Cl. CPC H10K 59/131; H10K 59/122

(57) ABSTRACT

Discussed are a display device and a display panel including a substrate having a display area and a non-display area adjacent the display area, a transistor disposed over the substrate, a base voltage line disposed over the substrate, a planarization layer disposed on the transistor and the base voltage line, a pixel electrode disposed on the planarization layer, a bank disposed on the pixel electrode and including an opening exposing a portion of the pixel electrode, an element intermediate layer located on the pixel electrode through the opening of the bank in a light emitting area and extending along the bank in a non-light emitting area, a common electrode disposed on the element intermediate layer, and a link area configured electrically interconnect the base voltage line and the common electrode and disposed in the display area.

### CROSS-REFERENCE TO RELATED APPLICATION

This application claims priority to Korean Patent Application No. 10-2023-0098653, filed on Jul. 28, 2023 in the Korean Intellectual Property Office, the entire contents of which is hereby expressly incorporated by reference into the present application.

### BACKGROUND

### Field

The present disclosure relates to electronic devices with displays, and more specifically, to a display panel and a display device.

### Discussion of the Related Art

An organic light emitting display device is a self-emission display device, and is a type of a display device using organic light emitting elements to emit light. Organic light emitting diodes (OLED) emit light when excitons, which are the combination of electrons and holes injected by an electrode (e.g., cathode) for electron injection and an electrode (e.g., anode) for hole injection into an emission layer, fall from an excited state to a ground state.

The organic light emitting display device can be configured with a top emission structure, a bottom emission structure, or a dual emission structure depending on a direction in which light is emitted, and can be driven by a passive matrix technique or an active matrix technique.

The organic light emitting display device can be thinner and lighter compared with other types of display devices, such as a liquid crystal display (LCD) device because the organic light emitting display device does not require separate back light. Further, the organic light emitting display device can consume much less power due to a low operating voltage characteristic, and can have excellent color reproduction, a faster response speed, a wider viewing angle, and a higher contrast ratio when compared to other types of display devices. Due to such excellent performance, work has been progressing on developing such light emitting display devices capable of providing a variety of advantages as a next generation display.

To provide high resolution and high luminance, the number of pixels per unit area included in an organic light emitting display device has been increased. However, an amount of current that can flow through a unit area can be restricted due to the light emitting structure of the organic light emitting display device. Indeed, an increase in applied current can cause the reliability of the organic light emitting display device to be reduced and the power consumption of the organic light emitting display device to be increased.

To address this issue, various structures have been proposed to improve luminous efficiency and lifetime, and reduce power consumption, of organic light emitting display devices.

In an organic light emitting display device, each of a plurality of subpixels included in each pixel can include an organic light emitting element such as an organic light emitting diode and a pixel circuit, and each organic light emitting element can be independently driven by each pixel circuit to emit light.

However, since each organic light emitting element included in the plurality of subpixels includes an element intermediate layer, such an organic light emitting display device can suffer from leakage current such as a lateral current flowing between adjacent subpixels through the element intermediate layer. Such a lateral current can be referred to as a horizontal leakage current.

For example, when subpixels of each pixel include an on subpixel and an off subpixel, the luminance of the on subpixel can be reduced as current flowing in the on subpixel leaks to the off subpixel adjacent to the on subpixel through an element intermediate layer. Thereby, grayscales, in particular, low grayscales, may not be fully presented, or luminance presented by a display panel may not be uniform across the entire display area of the display panel.

### SUMMARY OF THE DISCLOSURE

The present inventors have tried to address the issue of a horizontal leakage current flowing between adjacent subpixels through an element intermediate layer in a structure where each organic light emitting element included in subpixels includes the element intermediate layer.

The inventors have invented a display panel and a display device that are capable of cutting off leakage current flowing between subpixels.

One or more aspects of the present disclosure can provide a display panel and a display device that are configured to have a narrow bezel structure.

One or more aspects of the present disclosure can provide a display panel and a display device that have a high transmittance.

One or more aspects of the present disclosure can provide a display panel and a display device that are configured with a structure in which a common electrode and a base voltage line are connected.

According to one or more example embodiments of the present disclosure, a display device can be provided that includes a substrate including a display area and a non-display area outside of the display area, a transistor disposed over the substrate, a base voltage line disposed over the substrate, a planarization layer disposed on the transistor and the base voltage line, a pixel electrode disposed on the planarization layer, a bank disposed on the pixel electrode and including an opening exposing a portion of the pixel electrode, an element intermediate layer located on the pixel electrode through the opening of the bank in a light emitting area and extending along the bank in a non-light emitting area, a common electrode disposed on the element intermediate layer, and a link area configured to electrically interconnect the base voltage line and the common electrode and disposed in the display area.

According to one or more example embodiments of the present disclosure, a display panel can be provided that includes a substrate including a display area and a non-display area outside of the display area, a transistor disposed over the substrate, a base voltage line disposed over the substrate, a planarization layer disposed on the transistor and the base voltage line, a pixel electrode disposed on the planarization layer, a bank disposed on the pixel electrode and including an opening exposing a portion of the pixel electrode, an element intermediate layer located on the pixel electrode through the opening of the bank in a light emitting area, extending along the bank in a non-light emitting area, and including a hole formed on the bank, a common electrode disposed on the element intermediate layer, and a link area configured to electrically interconnect the base voltage line and the common electrode through the hole of the element intermediate layer.

According to one or more aspects of the present disclosure, a display panel and a display device can be provided that are capable of cutting off leakage current flowing between subpixels.

According to one or more aspects of the present disclosure, a display panel and a display device can be provided that are configured to have a narrow bezel structure.

According to one or more aspects of the present disclosure, a display panel and a display device can be provided that have a high transmittance.

According to one or more aspects of the present disclosure, a display panel and a display device can be provided that are configured with a structure in which a common electrode and a base voltage line are connected in a display area, and thereby, are capable of reducing a bezel.

According to one or more aspects of the present disclosure, a display panel and a display device can be provided that are capable of stably supplying a base voltage to a common electrode by applying an example structure in which the common electrode and a base voltage line are connected, According to one or more aspects of the present disclosure, a display panel and a display device can be provided that are capable of reducing resistance on a path through which a base voltage is supplied and reducing power consumption, and thereby, helping to be driven at low power.

### BRIEF DESCRIPTION OF THE DRAWINGS

FIG. 1 illustrates an example system configuration of a display device according to aspects of the present disclosure;

FIG. 2 illustrates an example configuration of a display panel according to aspects of the present disclosure.

FIG. 3 illustrates a vertical structure of an example display area of the display panel according to aspects of the present disclosure.

FIG. 4 is an example plan view of the display area of the display panel according to aspects of the present disclosure.

FIG. 5 is a cross-sectional view of an example stackup configuration of the display panel according to aspects of the present disclosure.

FIG. 6 is a cross-sectional view of an example stackup configuration of the display panel according to aspects of the present disclosure.

FIG. 7 is a cross-sectional view of an example stackup configuration of the display panel according to aspects of the present disclosure.

FIG. 8 is an example plan view of the display area of the display panel according to aspects of the present disclosure.

### DETAILED DESCRIPTION OF THE EMBODIMENTS

Reference will now be made in detail to example embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, with reference to the accompanying drawings, various example embodiments of the present disclosure will be described in detail.

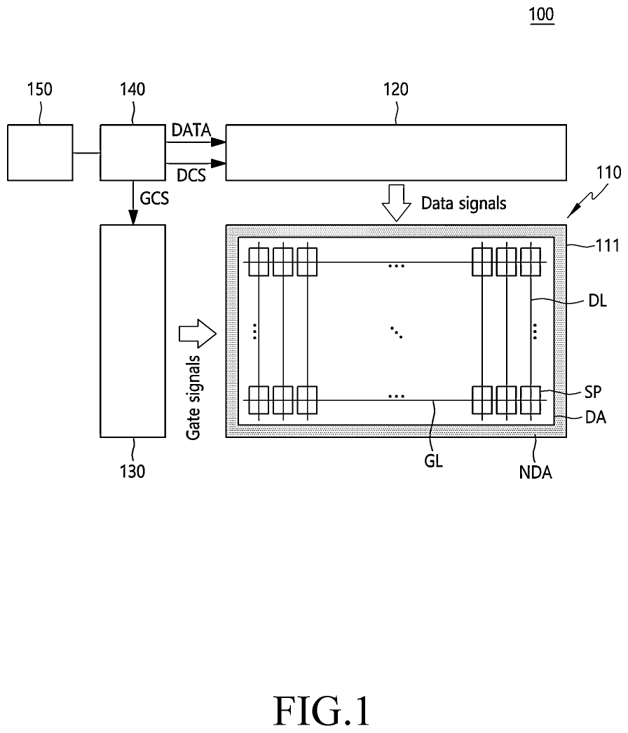

FIG. 1 illustrates the configuration of an example display device 100 according to aspects of the present disclosure. All components of each display apparatus according to all embodiments of the present disclosure are operatively coupled and configured.

Referring to FIG. 1, in one or more example embodiments, the display device 100 can include a display panel 110 and a display driving circuit as components for displaying an image. The display driving circuit can be a circuit for driving the display panel 110, and include a data driving circuit 120, a gate driving circuit 130, a display controller 140, and other circuit components.

The display panel 110 can include a substrate 111 and a plurality of subpixels SP disposed on the substrate 111.

The substrate 111 of the display panel 110 can include a display area DA allowing an image to be displayed and a non-display area NDA located outside of the display area DA.

In one or more aspects, the non-display area NDA of the display panel 110 can have a very small area compared with the display area DA. But embodiments of the present disclosure are not limited thereto.

For example, the non-display area NDA can include a first non-display area located outside of the display area DA in a first direction, a second non-display area located outside of the display area DA in a second direction intersecting the first direction, a third non-display area located outside of the display area DA in a direction opposite to the first direction, and a fourth non-display area located outside of the display area DA in a direction opposite to the second direction. One or two non-display areas among the first to fourth non-display areas can include a pad area to which the data driving circuit 120 is connected or bonded. In one or more aspects, among the first to fourth non-display areas, each of the remaining two or three non-display areas, which do not include the pad area, can have a very small size compared with the one or two non-display areas.

In one or more aspects, a boundary area between the display area DA and the non-display area NDA can be bent, and thereby, the non-display area NDA can be located under the display area DA. In this implementation, when a user views the display device 100 in front thereof, all or most of the non-display area NDA can be not visible to the user.

Various types of signal lines for driving a plurality of subpixels SP can be disposed on the substrate 111 of the display panel 110.

In one or more aspects, the display device 100 can be a liquid crystal display device, or the like, or a self-emission display device in which light is emitted from the display panel 110 itself. In an example where the display device 100 according to aspects of the present disclosure is the self-emission display device, each of the plurality of subpixels SP can include a light emitting element. But embodiments of the present disclosure are not limited thereto.

For example, the display device 100 according to aspects of the present disclosure can be an organic light emitting display device implemented with organic light emitting diodes (OLED) as light emitting elements. In another example, the display device 100 according to aspects of the present disclosure can be an inorganic light emitting display device implemented with inorganic material-based light emitting diodes as light emitting elements. In further another example, the display device 100 according to aspects of the present disclosure can be a quantum dot display device implemented with quantum dots, which are self-emission semiconductor crystals, as light emitting elements.

The structure of each of the plurality of subpixels SP can depend on types of display device 100. For example, when the display device 100 is a self-emission display device including self-emission subpixels SP, each subpixel SP can include a self-emission light emitting element, one or more transistors, and one or more capacitors. But embodiments of the present disclosure are not limited thereto.

The various types of signal lines can include, for example, a plurality of data lines DL for carrying data signals (which can be referred to as data voltages or image signals), a plurality of gate lines GL for carrying gate signals (which can be referred to as scan signals), and the like.

In one or more aspects, the plurality of data lines DL and the plurality of gate lines GL can intersect one another. For example, the plurality of data lines DL and the plurality of gate lines GL can intersect one another at a predefined angle. Each of the plurality of data lines DL can be configured to extend in a first direction, and each of the plurality of gate lines GL can be configured to extend in a second direction. For example, the first direction can be the column or vertical direction, and the second direction can be the row or horizontal direction. In another example, the first direction can be the row or horizontal direction, and the second direction can be the column or vertical direction. Hereinafter, for convenience of explanation, discussions can be provided based on examples where each of a plurality of data lines DL is disposed in the column direction, and each of a plurality of gate lines GL is disposed in the row direction, but example embodiments of the present disclosure are not limited thereto.

The data driving circuit 120 can be a circuit for driving a plurality of data lines DL and can output data signals to the plurality of data lines DL.

The data driving circuit 120 can receive image data DATA in digital form from the display controller 140, convert the received image data DATA into data signals in analog form, and output converted data signals to the plurality of data lines DL.

In one or more aspects, the data driving circuit 120 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique.

The data driving circuit 120 can be located in, and/or electrically connected to, but not limited to, only one side or portion (e.g., an upper edge or a lower edge) of the display panel 110. In one or more aspects, the data driving circuit 120 can be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or other design requirements.

The data driving circuit 120 can be connected to outside, or an edge, of the display area DA of the display panel 110, or be disposed in the display area DA of the display panel 110.

The gate driving circuit 130 can be a circuit for driving a plurality of gate lines GL and can output gate signals to the plurality of gate lines GL. The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 can be embedded into the display panel 110 by a gate-in-panel (GIP) technique. In an example where the gate driving circuit 130 is implemented by the gate-in-panel (GIP) technique, the gate driving circuit 130 can be disposed on the substrate 111 of the display panel 110 during the manufacturing process of the display panel 110 or display device 100. In one aspect, the gate driving circuit 130 included in the display device 100 can be disposed in the display area DA of the display panel 110. In this implementation, for example, the gate driving circuit 130 can be disposed in, and/or electrically connected to, but not limited to, a first area (e.g., a left area or a right area of the display area DA) of the display area DA of the display panel 110. In another example, the gate driving circuit 130 can be disposed in, and/or electrically connected to, but not limited to, a first area (e.g., a left area or a right area of the display area DA) and a second area (e.g., the right area or the left area of the display area DA) of the display area DA of the display panel 110.

Herein, the gate driving circuit 130 embedded in the display panel 110 using the gate-in-panel (GIP) technique can also be referred to as a “gate-in-panel circuit.”

The display controller 140 can be a device for controlling the data driving circuit 120 and the gate driving circuit 130, and can control driving timing for the plurality of data lines DL and driving timing for the plurality of gate lines GL.

The display controller 140 can supply a data driving control signal DCS to the data driving circuit 120 to control the data driving circuit 120, and supply a gate driving control signal GCS to the gate driving circuit 130 to control the gate driving circuit 130.

The display controller 140 can receive image data input from a host system 150 and supply image data DATA readable by the data driving circuit 120 based on the input image data to the data driving circuit 120.

The display controller 140 can be implemented in a separate component from the data driving circuit 120, or incorporated in the data driving circuit 120 and thus implemented in an integrated circuit.

The display controller 140 can be a timing controller used in the typical display technology or a controller or a control device capable of performing other control functions in addition to the function of the typical timing controller. In one or more embodiments, the display controller 140 can be a controller or a control device different from the timing controller, or a circuitry or a component included in the controller or the control device. The display controller 140 can be implemented using various circuits or electronic components such as an integrated circuit (IC), a field programmable gate array (FPGA), an application specific integrated circuit (ASIC), a processor, and/or the like. But embodiments of the present disclosure are not limited thereto.

The display controller 140 can be mounted on a printed circuit board, a flexible printed circuit, and/or the like and be electrically connected to the gate driving circuit 120 and the data driving circuit 130 through the printed circuit board, flexible printed circuit, and/or the like.

The display controller 140 can transmit signals to, and receive signals from, the data driving circuit 120 via one or more predefined interfaces. For example, such interfaces can include a low voltage differential signaling (LVDS) interface, an embedded clock point-point interface (EPI), a serial peripheral interface (SPI), and the like. However, example embodiments of the present disclosure are not limited thereto.

In one or more aspects, to provide a touch sensing function, as well as an image display function, the display device 100 can include a touch sensor, and a touch sensing circuit configured to sense the touch sensor and detect whether a touch is applied by an object such as a finger, a pen, or the like, or a location of the touch.

The touch sensing circuit can include a touch driving circuit configured to drive and sense the touch sensor and generate and output touch sensing data, and a touch controller capable of detecting whether a touch is applied or a location of the touch using the touch sensing data.

The touch sensor can include a plurality of touch electrodes. The touch sensor can further include a plurality of touch lines to electrically connect the plurality of touch electrodes to the touch driving circuit.

The touch sensor can be implemented in the form of a touch panel outside of the display panel 110 or be integrated inside of the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process.

The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit. In one or more aspects, the display device 100 can represent, but not limited to, a mobile terminal, such as a smart phone, a tablet, or the like, a monitor, a television (TV), or the like. Example embodiments of the present disclosure are not limited thereto. In one or more aspects, the display device 100 can be display devices, or include displays, of various types, sizes, and shapes for displaying information or images.’

In one or more example embodiments, the display device 100 can further include an electronic device such as a camera (e.g., an image sensor), a sensor capable of detecting an object, and the like. For example, the sensor can be a sensor capable of detecting an object or a human body by receiving light such as infrared light, ultrasonic light, ultraviolet light or the like. But embodiments of the present disclosure are not limited thereto.

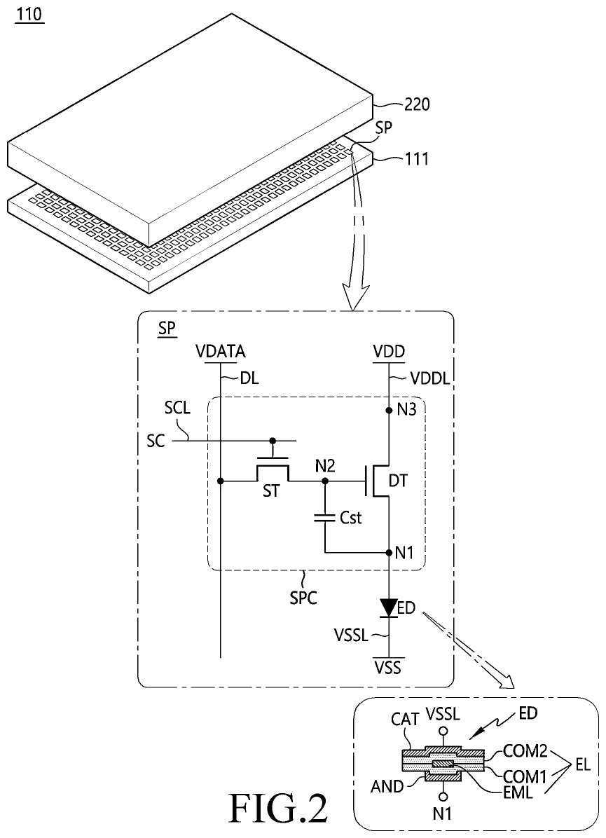

FIG. 2 illustrates an example configuration of the display panel 110 according to aspects of the present disclosure.

Referring to FIG. 2, the display panel 110 can include a substrate 111 on which a plurality of subpixels SP are disposed, and an encapsulation layer 220 over the substrate 111. The encapsulation layer 220 can also be referred to as an encapsulation substrate or an encapsulation stack.

Referring to FIG. 2, in an example where the display device 100 is a self-emission display device, each of the plurality of subpixels SP disposed on the substrate 111 can include a light emitting element ED and a subpixel circuit SPC for driving the light emitting element ED.

Referring to FIG. 2, the subpixel circuit SPC can include a plurality of pixel driving transistors and at least one capacitor for driving the light emitting element ED.

The subpixel circuit SPC can drive the light emitting element ED by supplying a driving current to the light emitting element ED at a predetermined timing. The light emitting element ED can emit light by being driven by the driving current.

The plurality of pixel driving transistors can include a driving transistor DT for driving the light emitting element ED and a scan transistor ST configured to be turned on or off by a scan signal SC. The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a display frame or a certain period of the display frame.

To drive one or more subpixels SP, at least one data signal VDATA, which is an image signal, and at least one scan signal SC, which is a gate signal, can be applied to one or more subpixels SP. Further, at least one common pixel driving voltage including a first driving voltage VDD and a second driving voltage VSS can be applied to the one or more subpixels SP.

The light emitting element ED can include a pixel electrode AND, an element intermediate layer EL, and a common electrode CAT. The element intermediate layer EL can be disposed between the pixel electrode AND and the common electrode CAT, and include an emission layer EML.

In an example where the light emitting element ED is an organic light emitting diode, the element intermediate layer EL can include the emission layer EML, a first common layer COM1 between the pixel electrode AND and the emission layer EML, and a second common layer COM2 between the emission layer EML and the common electrode. The emission layer EML can be disposed in each subpixel SP. The first common layer COM1 and the second common layer COM2 can be commonly disposed across all or some of a plurality of subpixels SP. The emission layer EML can be disposed in each subpixel SP, and the first common layer COM1 and the second common layer COM2 can be commonly disposed across a plurality of light emitting areas and a non-light emitting area.

For example, the first common layer COM1 can include a hole injection layer (HIL) and a hole transfer layer (HTL), and the second common layer COM2 can include an electron transport layer (ETL) and an electron injection layer (EIL). The hole injection layer can inject holes from the pixel electrode AND to the hole transport layer, the hole transport layer can transport holes to the emission layer EML, the electron injection layer can inject electrons from the common electrode CAT to the electron transport layer, and the electron transport layer can transport electrons to the emission layer EML.

For example, the common electrode CAT can be electrically connected to a second driving voltage line VSSL. A second driving voltage VSS, which is a type of common pixel driving voltage, can be applied to the common electrode CAT through the second driving voltage line VSSL.

The pixel electrode AND can be electrically connected to a first node N1 of a corresponding driving transistor DT of each subpixel SP. Herein, the second driving voltage VSS can also be referred to as a “base voltage”, and the second driving voltage line VSSL can also be referred to as a “base voltage line.

For example, the pixel electrode AND can be an anode electrode disposed in each subpixel SP, and the common electrode CAT can be a cathode electrode commonly disposed in a plurality of subpixels SP. In another example, the common electrode CAT can be an anode electrode disposed in each subpixel SP, and the pixel electrode AND can be a cathode electrode commonly disposed in a plurality of subpixels SP. Hereinafter, for convenience of explanation, discussions can be provided based on examples where the pixel electrode AND is an anode electrode, and the common electrode CAT is a cathode electrode.

Each light emitting element ED can be configured by respective portions of a corresponding pixel electrode AND, a corresponding portion of the element intermediate layer EL, and a corresponding portion of the common electrode CAT that overlap with each other. A corresponding light emitting area can be formed by each light emitting element ED. For example, a corresponding light emitting area of each light emitting element ED can include an area in which a corresponding pixel electrode AND, a corresponding portion of the element intermediate layer EL, and a corresponding portion of the common electrode CAT overlap with each other.

In one or more aspects, the light emitting element ED can be an organic light emitting diode (OLED), an inorganic material-based light emitting diode (LED), or a quantum dot light emitting element. For example, when the light emitting element ED is an organic light emitting diode OLED, the element intermediate layer EL of the light emitting element ED can be an organic element intermediate layer including an organic material. But embodiments of the present disclosure are not limited thereto.

The driving transistor DT can be a transistor configured to supply a driving current to the light emitting element ED. The driving transistor DT can be connected between a first driving voltage line VDDL and the light emitting element ED.

The driving transistor DT can include a first node N1 electrically connected with the light emitting element ED, a second node N2 to which a data signal VDATA is applied, and a third node N3 to which a driving voltage VDD from a driving voltage line DVL (e.g., the first driving voltage line VDDL) is applied.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL.

The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

In one or more aspects, the storage capacitor Cst, which can be present between the first node N1 and the second node N2 of the driving transistor DT, can be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like).

Each of the driving transistor DT and the scan transistor ST can be an n-type transistor or a p-type transistor.

For example, at least a portion of the subpixel circuit SPC can overlap with at least a portion of the light emitting element ED in the vertical direction. In another example, the subpixel circuit SPC may not overlap the light emitting element ED in the vertical direction. But embodiments of the present disclosure are not limited thereto.

As shown in FIG. 2, the subpixel circuit SPC can include two transistors (2T: DT and ST) and one capacitor (1C: Cst) (which can be referred to as a “2T1C structure”), and in some implementations, can further include one or more transistors, or further include one or more capacitors.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have an 7T1C structure including 7 transistors and 1 capacitor.

The types and number of gate signals supplied to a subpixel SP, and/or the types and number of gate lines connected to the subpixel SP can vary depending on a structure of a corresponding subpixel circuit SPC.

Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 220 can be disposed in the display panel 110 to prevent the external moisture or oxygen from penetrating into the circuit elements (e.g., the light emitting element ED). The encapsulation layer 220 can be disposed in various shapes or configurations to prevent light emitting elements ED from contacting moisture or oxygen.

In one or more aspects, the display panel 110 can have a top emission structure or a bottom emission structure.

In one or more aspects, the display device 100 can have an extremely narrow bezel structure in which the non-display area NDA of the display panel 110 is very small or almost absent.

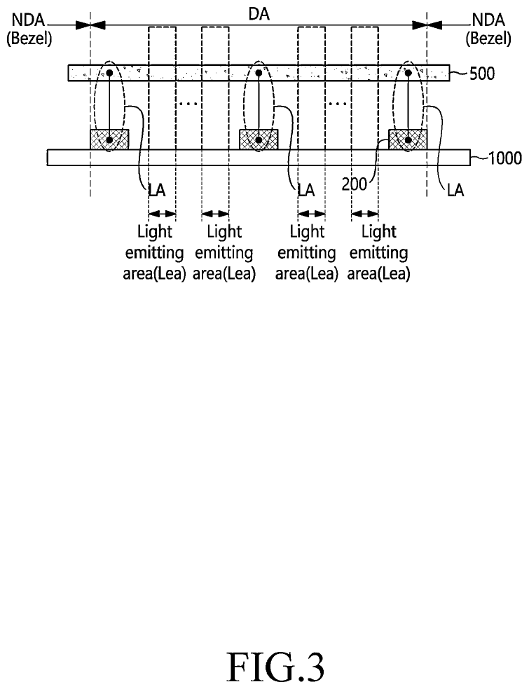

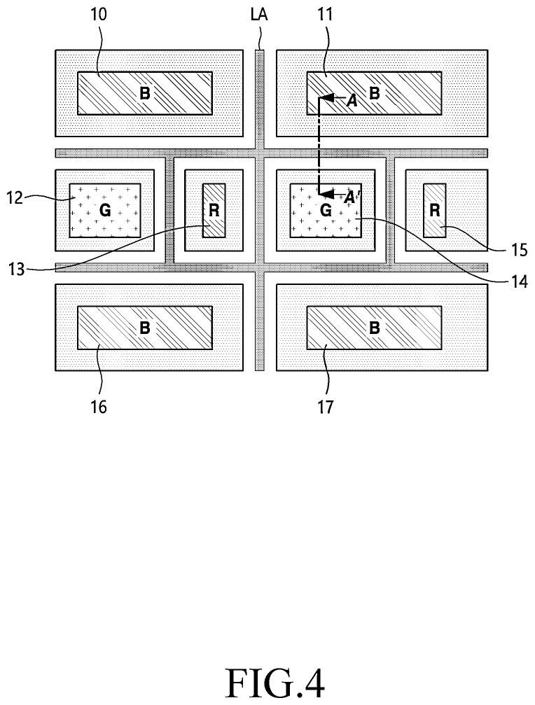

FIGS. 3 and 4 illustrate a vertical structure and a structure in a plan view of an example display area of the display panel 110 according to aspects of the present disclosure.

Referring to FIG. 3, in one or more example embodiments, the display panel 110 can include a substrate 1000, a base voltage line (VSSL, 200), a link area LA, a common electrode 500, and the like. It should be noted that in FIG. 3, other elements included in the display panel 110 are omitted for convenience of explanation.

Referring to the vertical structure of FIG. 3, the link area LA can be present from the base voltage line (VSSL, 200) to the common electrode 500 in the vertical direction. For example, the link area LA can electrically interconnect the base voltage line (VSSL, 200) and the common electrode 500 through at least one electrode formed in at least one layer between the base voltage line (VSSL, 200) and the common electrode 500. In various embodiments of the present disclosure, the display area DA can include one or more link areas LA, and one or more light emitting areas Lea. The display area DA can be interposed between opposite non-display areas NDAs, where the link areas LA and the light emitting areas Lea can be arranged sequentially and/or alternatingly in one or more directions.

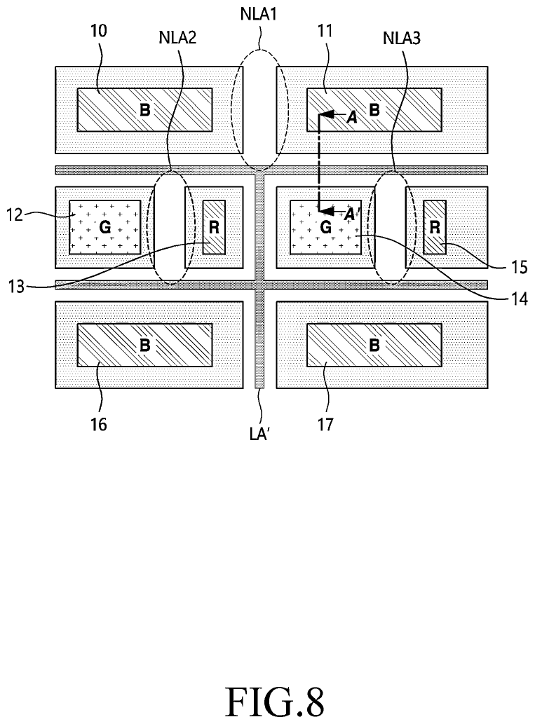

Referring to the plan view of FIG. 4, the link area LA can be disposed in the form of running between a plurality of light emitting elements (10 to 17) in the display area DA in first and second directions. It should be noted that FIG. 4 illustrates an example connection structure of the link area LA, but example embodiments of the present disclosure are not limited thereto. For example, as shown in FIG. 8, a link area LA can be disposed between some of a plurality of light emitting elements (10 to 17), rather than all of the plurality of light emitting elements (10 to 17). One or more areas where the link area LA is not disposed between the light emitting elements can be referred to as non-link areas (NLA1 to NLA3). Each light emitting element can be connected to a corresponding adjacent portion of the link area LA in the vertical structure.

Referring to the plan view of FIG. 4, the link area LA can be arranged in a matrix shape where the link area LA or extensions thereof can extend in at least one of a first direction and a second direction, where the first direction and the second direction intersect. When the link area LA is arranged in the matrix shape, one or more of the plurality of light emitting elements can be encircled by the link area LA (see light emitting elements 13 and 14) or can be partially surrounded by the link area (see light emitting elements 10, 11, 12, 15, 16 and 17) so that one or more sides of the light emitting elements can be open but other sides thereof are surrounded. Also, an arrangement of the link area LA can be symmetric in the display area DA.

In various embodiments of the present disclosure, the link area LA can include the second auxiliary electrode 420, the bride electrode 310, and/or the first auxiliary electrode, or one or more portions thereof. Accordingly, the link area LA can also be referred to as a link area structure.

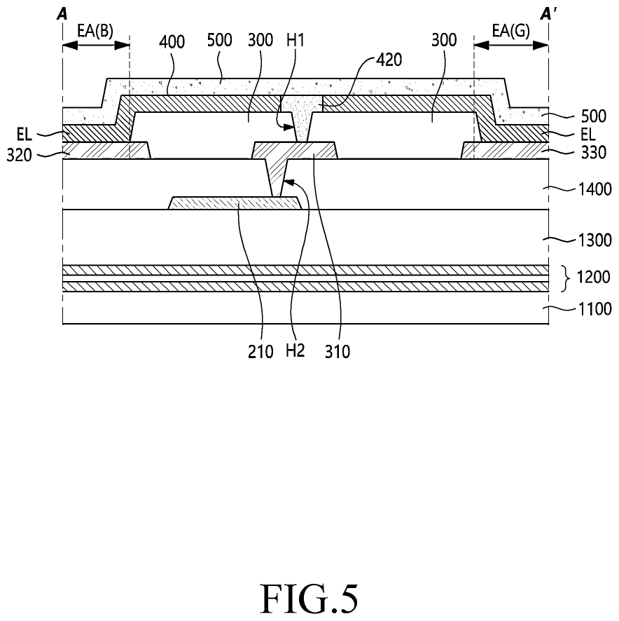

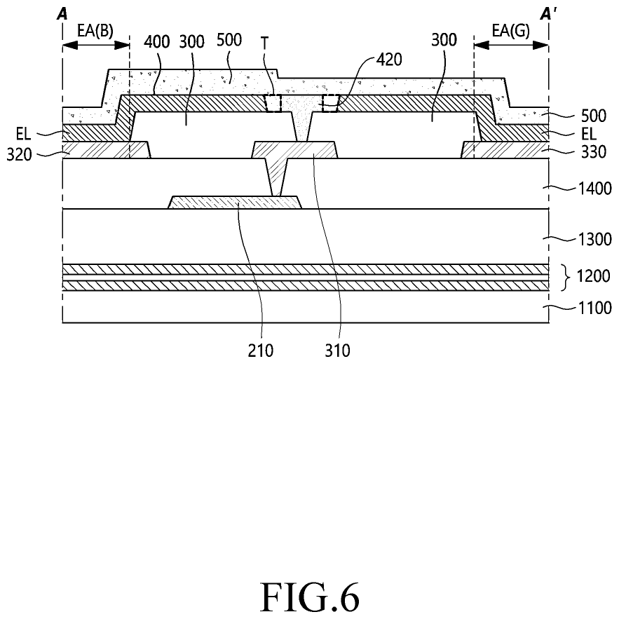

FIGS. 5 and 6 are cross-sectional views illustrating an example stackup configuration of the display panel 110 according to aspects of the present disclosure. FIG. 5 is a cross-sectional view taken along line A-A′ of FIG. 4.

Referring to FIG. 5, in one or more example embodiments, the display panel 110 can include a display area DA and a non-display area NDA. The display area DA can be located between portions of the non-display area NDA.

Referring to FIG. 5, the display panel 110 can include a substrate 1100, a dual polyimide (PI) substrate 1200, a base circuit layer 1300, a planarization layer 1400, a bank 300, and an element intermediate layer 400, the common electrode 500, and the link area LA.

The substrate 1100 can include the display area DA and the non-display area NDA.

The substrate 1100 can include glass and can be removed after the process of fabricating the display panel 110 is completed.

The PI substrate 1200 can include a flexible plastic material, for example, polyimide (PI). But embodiments of the present disclosure are not limited thereto. When the PI substrate 1200 is configured with a polyimide layer, moisture can penetrate into the substrate configured with the polyimide (PI) layer and affect thin film transistors or light emitting elements located on the substrate.

To prevent this situation, the PI substrate 1200 can have a stack of two base layers, and a silicon oxide (SiOx) layer with excellent moisture permeability can be disposed between the two base layers. The silicon oxide (SiOx) layer can prevent moisture from entering the lower base layer of the PI substrate 1200, and the performance and reliability of the display panel 110 can be improved. But embodiments of the present disclosure are not limited thereto, and other materials can be used.

As shown in FIGS. 5 and 6, the PI substrate 1200 can be configured with two base layers including a polyimide material, and further can include an intermediate layer IPD including a material such as silicon oxide or an inorganic material between the two layers.

The base circuit layer 1300 can be disposed on the PI substrate 1200 and can include thin film transistors (TFT) and the like disposed in the display area DA.

The planarization layer 1400 can be configured to have a flat surface on the transistors disposed on the substrate 1100. Each transistor can be an n-type transistor, or a p-type transistor. The planarization layer 1400 can include an insulating material, and can be an inorganic layer or an organic layer.

The bank 300 can be disposed on the planarization layer 1400 and can define a light emitting area EA of each subpixel and a non-light emitting area in the display area DA. Referring to FIG. 5, the bank 300 can define a portion of the display area where an emission layer is disposed between a pixel electrode and the common electrode as a light emitting area, and a portion of the display area where the emission layer is not disposed between the pixel electrode and the common electrode as a non-light emitting area.

For example, the bank 300 can be disposed on the pixel electrode and can including an opening exposing a portion of the pixel electrode.

The element intermediate layer 400 can be disposed on the pixel electrode, and include a first common layer extending to the top of the bank 300, the emission layer disposed on the first common layer, and a second common layer disposed on the emission layer and extending along the first common layer, which extends to the top of the bank. A hole can be formed in the first common layer and the second common layer on the top of the bank, and the link area can electrically interconnect the common electrode 500 and a base voltage line VSSL through the hole.

Referring to FIGS. 5 and 6, two pixel electrodes (320 and 330) and a bridge electrode 310 disposed on the planarization layer 1400 can be insulated from each other by the bank 300.

FIG. 6 illustrates light emitting areas (EA(B) and EA(G)) located on both sides, and a non-light emitting area, which is the remaining area except for the light emitting areas (EA(B) and EA(G)), in the cross-sectional view of an example portion of the display area DA. The link area LA can be disposed in the non-light emitting area of the display area DA.

The light emitting areas can be defined by openings in the bank. The openings of the bank 300 can correspond to the light emitting areas. The bank can also referred to as a light emitting part defining layer.

Referring to FIGS. 5 and 6, the bank 300 can be located on the pixel electrodes (310, 320, and 330) and can include openings exposing portions of the pixel electrodes (310, 320, and 330). The openings of the bank 300 can correspond to light emitting areas.

The display panel 110 can include a link area LA configured to electrically interconnect the common electrode 500 (e.g., cathode,) and a base voltage line VSSL in the display area DA.

Referring to FIG. 5, the link area LA can include at least one first auxiliary electrode 210 located under the planarization layer 1400, and a second auxiliary electrode 420 located on the bank 300 and electrically interconnecting the common electrode 500 and the first auxiliary electrode 210.

The second auxiliary electrode 420 can electrically interconnect the common electrode 500 and the first auxiliary electrode 210 through a hole. The first auxiliary electrode 210 can be the base voltage line VSSL or an electrode electrically connected to the base voltage line VSSL. The link area LA can further include at least one bridge electrode 310 for electrical interconnecting the first auxiliary electrode 210 and the second auxiliary electrode 420. The bridge electrode 310 can be located between the planarization layer 1400 and the bank 300. The bridge electrode 310 can include the same material as the pixel electrode.

The first auxiliary electrode 210 can include the same material as a material included in the source electrode or drain electrode of a transistor, or can include the same material as a material included in an electrode electrically connected to the source electrode or drain electrode of the transistor.

Referring to FIG. 5, the common electrode 500 can be electrically connected to the second auxiliary electrode 420 through a hole of the element intermediate layer EL, the second auxiliary electrode 420 can be electrically connected to the bridge electrode 310 through a hole H1 of the bank 300, and the bridge electrode 310 can be electrically connected to the first auxiliary electrode 210 through a hole H2 of the planarization layer 1400.

The second auxiliary electrode 420 connected to the common electrode 500 can be disposed in an area where a portion of the element intermediate layer 400 is removed on a subpixel basis. For example, the second auxiliary electrode 420 can be disposed inside of the hole H1. For example, the second auxiliary electrode 420 can contact one or more side portions of the hole H1. But embodiments of the present disclosure are not limited thereto.

Referring to FIG. 5, a vertical arrangement of the holes H1 and H2 can be offset so that the hole H1 and the hole H2 are not vertically aligned. But embodiments of the present disclosure are not limited thereto, and in other embodiments, the holes H1 and H2 can be aligned vertically. In this regard, the first auxiliary electrode 210, the bride electrode 310 and the second auxiliary electrode 420 can also be aligned or can be not overlapping with each other or with one or more of the holes H1 and H2.

As shown in FIG. 5, the second auxiliary electrode 420 can be disposed on side surfaces of the first common layer COM1 and the second common layer COM2.

For example, the second auxiliary electrode 420 can contact the side surfaces of the first common layer COM1 and the second common layer COM2.

In another example, as shown in FIG. 6, the second auxiliary electrode 420 can be spaced apart from the side surfaces of the first common layer COM1 and the second common layer COM2.

The common electrode 500 can be disposed on the link area LA. The common electrode 500 can be in the form of a surface electrode. The common electrode 500 can be configured with a transparent electrode.

The link area LA can be disposed to be spaced apart from an area of the display area DA where a light emitting element ED is formed. The link area LA can be commonly connected to the common electrode 500 along with the light emitting element ED.

The link area LA can include a material having a higher resistivity than the resistivity of the common electrode 500.

The at least one first auxiliary electrode 210, the at least one bridge electrode 310, and the at least one second auxiliary electrode 420 can be arranged in the vertical direction to be electrically connected to each other.

The first auxiliary electrode 210 can be a base voltage line VSSL to which a base voltage VSS is applied, or can be an electrode connected to the base voltage line VSSL.

Referring to FIG. 3, the display panel 110 can further include a plurality of subpixels SP, and each of the plurality of subpixels can include a light emitting element and one or more transistors. Each light emitting element can be configured by overlapping of a pixel electrode, an element intermediate layer, and a common electrode. The link area LA can be located between a light emitting area of a first subpixel and a light emitting area of a second subpixel among the plurality of subpixels.

As described above, in one or more aspects, one or more portions of the element intermediate layer 400 disposed adjacent to subpixels can be removed through a laser process. Thereby, a current path in the element intermediate layer 400 can be cut off, this leading to a leakage current being prevented. By applying this configuration, damage caused by leakage current between different subpixels can be prevented. By cutting off leakage current between subpixels, an OLED panel with high efficiency and reduced power consumption can be implemented.

Referring to FIGS. 5 and 6, as the link area LA is disposed such that two or more auxiliary electrodes (i.e., the first and second auxiliary electrodes (210 and 420), or the first and second auxiliary electrodes (210 and 420) and the bridge electrode 310) directly contact, and are connected to, the common electrode 500, a common electrode contact area can be not disposed in a bezel area of the display panel 110. As a result, the bezel area can be reduced by approximately 200 μm, and a narrow bezel can be realized.

Meanwhile, there is a trade-off between resistance and transmittance of metal of the common electrode 500 disposed in the display panel 110. In an example where elements are connected to the common electrode 500 in the display panel 110 configured with a top emission structure, as the metal thickness of the common electrode 500 is greater, corresponding resistance can be smaller, and thereby, an IR rising phenomenon can be improved. In contrast, as the metal thickness of the common electrode 500 is greater, the transmittance of the display panel can be reduced.

To address this issue, as the link area LA, which is configured with two or more auxiliary electrodes (i.e., the first and second auxiliary electrodes (210 and 420), or the first and second auxiliary electrodes (210 and 420) and the bridge electrode 310), is connected to a lower portion of the common electrode 500, the display panel can provide an advantage of increasing the sheet resistance of the common electrode 500. Thereby, the thickness of the common electrode 500 can be reduced relative to the increased resistance, and the transmittance of the display panel 110 can be increased.

Referring to FIG. 4, as the link area LA is disposed in the form of line in a plan view, this implementation can be applied to the display panel 110 configured to have a large area. Thus, as a common electrode thickness in the display panel 110 with such a large area can be reduced, this implementation can help to improve the transmittance of the display panel 110.

Referring back to FIG. 5, in one example embodiment, the second auxiliary electrode 420 can be formed in a portion of the element intermediate layer 400, which is removed by a laser process, and in or on an upper portion of the bank 300, and thereby, side surfaces of the second auxiliary electrode 420 can contact the element intermediate layer EL.

Referring to FIG. 6, in one example embodiment, after a portion of the element intermediate layer 400 is removed by a laser lift process, the second auxiliary electrode 420 can be formed in the portion of the element intermediate layer 400 and in or on an upper portion of the bank 300, and thus, side surfaces of the second auxiliary electrode 420 may not contact the element intermediate layer EL. For example, the second auxiliary electrode 420 and each element intermediate layer EL can be spaced apart from each other. In this implementation, a trench T can be formed between the second auxiliary electrode 420 and each element intermediate layer EL, but embodiments of the present disclosure are not limited thereto, and a non-conductive material can be positioned between the second auxiliary electrode 420 and each element intermediate layer EL, to fill the trench T, for example. In various embodiments of the present disclosure, a size or width of the trench T can be about the same as the hole H2, but embodiments of the present disclosure are not limited thereto, and the size or width of the trench T can be different from that of the hole H2. In other embodiment of the present disclosure, a total size or width of the trench and the second auxiliary electrode 420 can be about the same or less than that of the bride electrode 310, but embodiments of the present disclosure are not limited thereto.

For example, a photolithography mask, which has a much better tolerance than the laser processing, can be used to form the second auxiliary electrode 420.

Further, as the second auxiliary electrode 420 and each element intermediate layer EL are spaced apart to insulate each other, thereby, a leakage current can be effectively cut off, and noise generation can be eliminated or reduced.

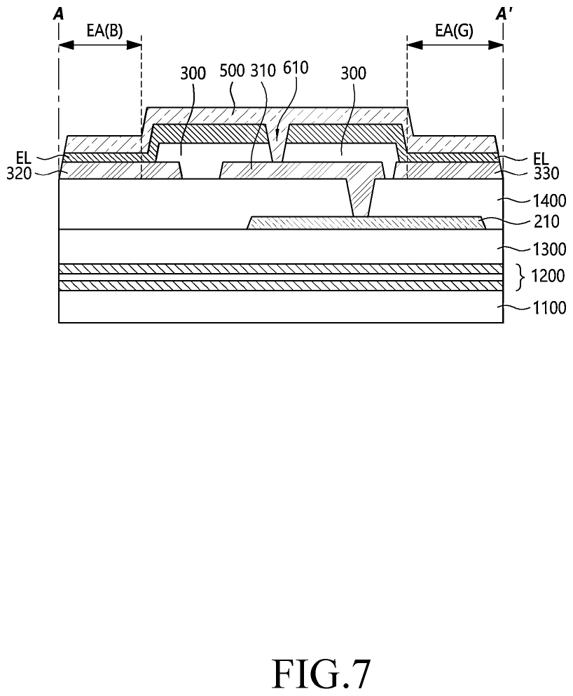

FIG. 7 is a cross-sectional view of an example stackup configuration of the display panel 110 according to aspects of the present disclosure. It should be noted that among elements illustrated in FIG. 7, some elements with the same reference numerals as those illustrated in FIGS. 5 and 6 can be the same elements or have the same functions.

Referring to FIG. 7, in one or more example embodiments, the display panel 110 can include a substrate 1100, a dual PI substrate 1200, a base circuit layer 1300, a planarization layer 1400, a bank 300, an element intermediate layer EL, a common electrode 500, and a link area LA.

The substrate 1100 can include a display area DA and a non-display area NDA.

The substrate 1100 can include glass and can be removed after the process of fabricating the display panel 110 is completed.

The PI substrate 1200 can include a flexible plastic material, for example, polyimide (PI). But embodiments of the present disclosure are not limited thereto. When the PI substrate 1200 is configured with a polyimide layer, moisture can penetrate into the substrate configured with the polyimide (PI) layer and affect thin film transistors or light emitting elements located on the substrate.

To prevent this situation, the PI substrate 1200 can have a stack of two base layers, and a silicon oxide (SiOx) layer with excellent moisture permeability can be disposed between the two base layers. The silicon oxide (SiOx) layer can prevent moisture from entering the lower base layer of the PI substrate 1200, and the performance and reliability of the display device 100 or the display panel 110 can be improved. But embodiments of the present disclosure are not limited thereto, and other materials can be used.

As shown in FIG. 7, the PI substrate 1200 can be configured with two base layers including a polyimide material, and further can include an intermediate layer IPD including a material such as silicon oxide or an inorganic material between the two layers.

The base circuit layer 1300 can be disposed on the PI substrate 1200 and can include thin film transistors (TFT) and the like disposed in the display area DA.

The planarization layer 1400 can be configured to have a flat surface on the transistors disposed on the substrate 1100. Each transistor can be an n-type transistor, or a p-type transistor. The planarization layer 1400 can include an insulating material, and can be an inorganic layer or an organic layer.

The bank 300 can be disposed on the planarization layer 1400 and can define a light emitting area EA and a non-light emitting area in the display area DA. The bank 300 can define a portion of the display area where an emission layer is disposed between a pixel electrode and a common electrode as a light emitting area, and a portion of the display area where the emission layer is not disposed between the pixel electrode and the common electrode as a non-light emitting area.

Two pixel electrodes (320 and 330) and a bridge electrode 310 disposed on the planarization layer 1400 can be insulated from each other by the bank 300.

For example, light emitting areas can be defined by openings in the bank. The openings of the bank 300 can correspond to the light emitting areas. The bank can also referred to as a light emitting part defining layer.

The bank 300 can be located on the planarization layer 1400 and can have openings exposing a portion of each pixel electrode 320. The openings of the bank 300 can correspond to light emitting areas.

The display panel 110 can include a second link area LA′ configured to interconnect the common electrode 500 (e.g., cathode) and a base voltage line VSSL in the display area DA.

Referring to FIG. 7, the second link area LA′ can include at least one first auxiliary electrode 210 located under the planarization layer 1400, and at least one hole electrode 610 located on the bank 300 and electrically interconnecting the common electrode 500 and the first auxiliary electrode 210, or one or more portions thereof. The second link area LA′ can also be referred to as a link area structure.

Referring to FIG. 7, the hole electrode 610 can be formed such that the common electrode 500 is extended into holes formed in respective portions of the element intermediate layer EL and the bank 300.

The hole electrode 610 can electrically interconnect the common electrode 500 and the first auxiliary electrode 210 through the holes.

The second link area LA′ can further include at least one bridge electrode 310 for electrically interconnecting the at least one first auxiliary electrode 210 and the at least one hole electrode 610. The bridge electrode 310 can be located between the planarization layer 1400 and the bank 300. The bridge electrode 310 can include the same material as the pixel electrode.

The first auxiliary electrode 210 can include the same material as a material included in the source electrode or drain electrode of a transistor, or can include the same material as a material included in an electrode electrically connected to the source electrode or drain electrode of the transistor.

The hole electrode 610 can be electrically connected to the bridge electrode 310 through holes formed in respective portions of the element intermediate layer EL and the bank 300, and the bridge electrode 310 can be connected to the first auxiliary electrode 210 through a hole of the planarization layer 1400.

The common electrode 500 can be disposed on the second link area LA′. The common electrode 500 can be in the form of a surface electrode. The common electrode 500 can be configured with a transparent electrode.

The second link area LA′ can be disposed to be spaced apart from an area of the display area DA where a light emitting element ED is formed.

The second link area LA′ can include a material having a higher resistivity than the resistivity of the common electrode 500.

The at least one first auxiliary electrode 210, the at least one bridge electrode 310, and the at least one hole electrode 610 can be arranged in the vertical direction to be electrically connected to each other.

The first auxiliary electrode 210 can be a base voltage line VSSL to which a base voltage VSS is applied, or can be an electrode connected to the base voltage line VSSL.

In an example where the display panel 110 is configured with the top emission structure, a transparent electrode can be used as the common electrode 500, and the resistance of the transparent electrode can be greater than that of a typical metal. Therefore, the structure connected using the second auxiliary electrode 420 disclosed in FIGS. 5 and 6 can maximize a reduction in resistance of the auxiliary electrode, compared to the structure of FIG. 7 in which the transparent electrode 610 is formed even inside of the holes.

Further, since the auxiliary electrode in FIGS. 5 and 6 has a structure in which the first auxiliary electrode and the second auxiliary electrode are disposed in parallel to each other, configurations of FIGS. 5 and 6 including the two auxiliary electrodes (210 and 420) can have reduced resistance and be advantageous in terms of IR drop, compared to the structure of including only the first auxiliary electrode in FIG. 7.

The display panel structure of FIG. 7 can be formed more easily in terms of manufacturing process compared to the display panel structures of FIGS. 5 and 6 because the deposition of the common electrode 500 extends to the holes formed in the respective portions of the bank 300 and the element intermediate layer 400.

The display panel structure of FIG. 7 can improve leakage current by removing a portion of the element intermediate layer (400 or EL) around, or adjacent to, a subpixel through a laser process, and thereby, cutting off a current path in the element intermediate layer 400. By applying this configuration, damage caused by leakage current between different subpixels can be prevented. By cutting off leakage current between subpixels, an OLED panel with high efficiency and reduced power consumption can be implemented.

Referring to FIGS. 7 and 8, as the second link area LA′ is disposed such that the auxiliary electrode 210, the bridge electrode 310, and the hole electrode 610 directly contact, and are connected to, the common electrode 500, a common electrode contact area ca be not disposed in a bezel area of the display panel 110. As a result, the bezel area can be reduced by approximately 200 μm, and a narrow bezel can be realized.

As the second link area LA′, which is configured with the single auxiliary electrode 210, the bridge electrode 310, and the hole electrode 610, is connected to a lower portion of the common electrode 500, the display panel can provide an advantage of increasing the sheet resistance of the common electrode 500. Thereby, the thickness of the common electrode 500 can be reduced relative to the increased resistance, and the transmittance of the display panel 110 can be increased.

Referring to FIG. 8, as the second link area LA′ is disposed in the form of line in a plan view, this implementation can be applied to the display panel 110 configured to have a large area. Thus, as a common electrode thickness in the display panel 110 with such a large area can be reduced, this implementation can help to improve the transmittance of the display panel 110.

The example embodiments described herein can be briefly discussed as follows.

According to the example embodiments described herein, a display device can be provided that includes a substrate including a display area and a non-display area outside of the display area, a transistor disposed over the substrate, a base voltage line disposed over the substrate, a planarization layer disposed on the transistor and the base voltage line, a pixel electrode disposed on the planarization layer, a bank disposed on the pixel electrode and including an opening exposing a portion of the pixel electrode, an element intermediate layer located on the pixel electrode through the opening of the bank in a light emitting area and extending along the bank in a non-light emitting area, a common electrode disposed on the element intermediate layer, and a link area configured to electrically interconnect the base voltage line and the common electrode and disposed in the display area.

In one or more aspects, the element intermediate layer can include a hole formed on the bank, and the link area can electrically interconnect the base voltage line and the common electrode through the hole.

In one or more aspects, the link area can include a first auxiliary electrode located under the planarization layer, and a second auxiliary electrode located on the bank and electrically interconnecting the common electrode and the first auxiliary electrode. The second auxiliary electrode can electrically interconnect the common electrode and the first auxiliary electrode through the hole, and the first auxiliary electrode can be the base voltage line or an electrode electrically connected to the base voltage line. In one or more aspects, the second auxiliary electrode can be disposed inside of the hole.

In one or more aspects, the second auxiliary electrode can be spaced apart from one or more side portions of the hole. In one or more aspects, the second auxiliary electrode can contact one or more side portions of the hole.

In one or more aspects, the link area can further include a bridge electrode for electrically interconnecting the first auxiliary electrode and the second auxiliary electrode, and the bridge electrode can be located between the planarization layer and the bank.

In one or more aspects, the bridge electrode can include a same material as the pixel electrode.

In one or more aspects, the first auxiliary electrode can include a same material as a source electrode or drain electrode of the transistor, or a same material as an electrode electrically connected to the source electrode or drain electrode of the transistor.

In one or more aspects, the common electrode can be configured with a transparent electrode.

In one or more aspects, the link area can include a material having a resistivity higher than the common electrode.

In one or more aspects, the display device can further include a plurality of subpixels, and each of the plurality of subpixels can include a light emitting element and the transistor. The light emitting element can be configured by overlapping of the pixel electrode, the element intermediate layer, and the common electrode with each other, and the link area can be located between a first subpixel and a second subpixel among the plurality of subpixels.

According to the example embodiments described herein, a display panel can be provided that includes a substrate including a display area and a non-display area outside of the display area, a transistor disposed over the substrate, a base voltage line disposed over the substrate, a planarization layer disposed on the transistor and the base voltage line, a pixel electrode disposed on the planarization layer, a bank disposed on the pixel electrode and including an opening exposing a portion of the pixel electrode, an element intermediate layer located on the pixel electrode through the opening of the bank in a light emitting area, extending along the bank in a non-light emitting area, and including a hole formed on the bank, a common electrode disposed on the element intermediate layer, and a link area configured to electrically interconnect the base voltage line and the common electrode through the hole of the element intermediate layer.

In one or more aspects, the link area can include a first auxiliary electrode located under the planarization layer, and a second auxiliary electrode located on the bank and electrically interconnecting the common electrode and the first auxiliary electrode. The second auxiliary electrode can electrically interconnect the common electrode and the first auxiliary electrode through the hole, and the first auxiliary electrode can be the base voltage line or an electrode electrically connected to the base voltage line.

In one or more aspects, the second auxiliary electrode can be disposed inside of the hole. In one or more aspects, the second auxiliary electrode can be spaced apart from one or more side portions of the hole. In one or more aspects, the second auxiliary electrode can contact one or more side portions of the hole.

In one or more aspects, the link area can further include a bridge electrode for electrically interconnecting the first auxiliary electrode and the second auxiliary electrode, and the bridge electrode can be located between the planarization layer and the bank.

In one or more aspects, the bridge electrode can include a same material as the pixel electrode.

In one or more aspects, the first auxiliary electrode can include a same material as a source electrode or drain electrode of the transistor, or a same material as an electrode electrically connected to the source electrode or drain electrode of the transistor.

In one or more aspects, the common electrode can be configured with a transparent electrode.

In one or more aspects, the link area can include a material having a resistivity higher than the common electrode. In one or more aspects, the link area can be located in the display area.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A display device comprising:
a substrate comprising a display area and a non-display area adjacent the display area;
a transistor disposed over the substrate;
a base voltage line disposed over the substrate;
a planarization layer disposed on the transistor and the base voltage line;
a pixel electrode disposed on the planarization layer;
a bank disposed on the pixel electrode and comprising an opening exposing a portion of the pixel electrode;
an element intermediate layer located on the pixel electrode through the opening of the bank in a light emitting area and extending along the bank in a non-light emitting area;
a common electrode disposed on the element intermediate layer; and
a link area configured to electrically interconnect the base voltage line and the common electrode and disposed in the display area.

2. The display device of claim 1, wherein the element intermediate layer comprises a hole formed in the bank, and the link area electrically interconnects the base voltage line and the common electrode through the hole.

3. The display device of claim 2, wherein the link area comprises:
a first auxiliary electrode located under the planarization layer; and
a second auxiliary electrode located on the bank and electrically interconnecting the common electrode and the first auxiliary electrode,
wherein the second auxiliary electrode electrically interconnects the common electrode and the first auxiliary electrode through the hole, and
wherein the first auxiliary electrode is the base voltage line or an electrode electrically connected to the base voltage line.

4. The display device of claim 3, wherein the second auxiliary electrode is disposed inside the hole.

5. The display device of claim 4, wherein the second auxiliary electrode is spaced apart from one or more side portions of the hole.

6. The display device of claim 4, wherein the second auxiliary electrode contacts one or more side portions of the hole.

7. The display device of claim 3, wherein the link area further comprises a bridge electrode for electrical interconnecting the first auxiliary electrode and the second auxiliary electrode, and
wherein the bridge electrode is located between the planarization layer and the bank.

8. The display device of claim 7, wherein the bridge electrode comprises a same material as the pixel electrode.

9. The display device of claim 3, wherein the first auxiliary electrode comprises a same material as a source electrode or drain electrode of the transistor, or a same material as an electrode electrically connected to the source electrode or drain electrode of the transistor.

10. The display device of claim 1, wherein the common electrode is configured with a transparent electrode.

11. The display device of claim 1, wherein the link area comprises a material having a resistivity higher than that of the common electrode.

12. The display device of claim 1, further comprising a plurality of subpixels,
wherein the transistor is provided in plural,
wherein each of the plurality of subpixels comprises a light emitting element and a transistor of the plurality of transistors, and
wherein the light emitting element is configured by overlapping of the pixel electrode, the element intermediate layer, and the common electrode with each other, and the link area is located between a first subpixel and a second subpixel among the plurality of subpixels.

13. A display panel comprising:
a substrate comprising a display area and a non-display area adjacent the display area;
a transistor disposed over the substrate;
a base voltage line disposed over the substrate;
a planarization layer disposed on the transistor and the base voltage line;
a pixel electrode disposed on the planarization layer;
a bank disposed on the pixel electrode and including an opening exposing a portion of the pixel electrode;
an element intermediate layer located on the pixel electrode through the opening of the bank in a light emitting area, extending along the bank in a non-light emitting area, and comprising a hole formed on the bank,
a common electrode disposed on the element intermediate layer; and
a link area configured to electrically interconnect the base voltage line the common electrode through the hole of the element intermediate layer.

14. The display panel of claim 13, wherein the link area further comprises:
a first auxiliary electrode located under the planarization layer; and
a second auxiliary electrode located on the bank and electrically interconnecting the common electrode and the first auxiliary electrode,
wherein the second auxiliary electrode electrically interconnects the common electrode and the first auxiliary electrode through the hole, and
wherein the first auxiliary electrode is the base voltage line or an electrode electrically connected to the base voltage line.

15. The display panel of claim 14, wherein the second auxiliary electrode is disposed inside the hole.

16. The display panel of claim 15, wherein the second auxiliary electrode is spaced apart from one or more side portions of the hole.

17. The display panel of claim 13, wherein the link area is located in the display area.

18. A display device comprising:
the display panel of claim 13;
a data driving circuit to output data signals to a plurality of data lines of the display panel;
a gate driving circuit to output gate signal to a plurality of gate lines of the display panel; and
a display controller configure to control the data driving circuit and the gate driving circuit, and control driving timing for the plurality of data lines and driving timing for the plurality of gate lines.

19. A display device comprising:
a substrate comprising a display area and a non-display area adjacent to the display area;
a first auxiliary electrode on the substrate;
a planarization layer on the base voltage line;
a plurality of light emitting elements;
a bank between the plurality of light emitting elements;
a common electrode on the plurality of light emitting elements and the bank; and
a link area between the plurality of light emitting elements and electrically interconnecting the first auxiliary electrode and the common electrode.

20. The display device of claim 19, wherein the plurality of light emitting elements include a first light emitting element and a second light emitting element,
wherein the first light emitting element includes a first pixel electrode, a first element intermediate layer on the first pixel electrode and the bank, and a first portion of the common electrode on the first element intermediate layer,
wherein the second light emitting element includes a second pixel electrode, a second element intermediate layer on the second pixel electrode and the bank, and a second portion of the common electrode on the second element intermediate layer, and
a second auxiliary electrode coplanar with the first element intermediate layer and the second element intermediate layer, and interposed between the first element intermediate layer and the second element intermediate layer.
